(19) United States
(12) Patent Application Publication
(10) Pub. No.: US 2009/0109623 A1
(43) Pub. Date: Apr. 30, 2009

(54) HEAT-RADIATING MODULE WITH COMPOSITE PHASE-CHANGE HEAT-RADIATING EFFICIENCY

(75) Inventors: Yung-Li JANG, Dongshan Township (TW); Yau-Yuen Tung, Chu Pei City (TW); Ming-Cyuan Shih, Jhubei City (TW); Liang-Sheng Chang, Tianliao Village (TW)

Correspondence Address: EGBERT LAW OFFICES, 412 MAIN STREET, 7TH FLOOR, HOUSTON, TX, 77002, US

(73) Assignee: FORCECON TECHNOLOGY Co., Ltd., Chu Pei City (TW)

(21) Appl. No.: 11/932,334

(22) Filed: Oct. 31, 2007

(51) Int. Cl. H05K 7/20

(52) U.S. Cl. 361/700; 165/104.21; 361/703

(57) ABSTRACT

The present invention provides a heat-radiating module with composite phase-change heat-radiating efficiency. The cooling pad of the heat-radiating module is fitted with a heating portion and radiating portion. The first and second chambers are placed at intervals into the cooling pad. The first and second phase-change materials are separately placed in two chambers. The reaction temperatures of two phase-change materials differ from each other. The phase-change material of higher reaction temperature assists in heat-absorbing and preventing overheating. There is a heat peak when the cooling pad reaches the preset high-temperature state. When the temperature of the cooling pad declines below a preset temperature, the phase-change material of lower reaction temperature will release the stored latent heat, enabling the cooling pad to maintain an operating temperature and improve the heat-radiating efficiency in a variety of equipment.

### CROSS-REFERENCE TO RELATED U.S. APPLICATIONS

Not applicable.

### STATEMENT REGARDING FEDERALLY SPONSORED RESEARCH OR DEVELOPMENT

Not applicable.

### NAMES OF PARTIES TO A JOINT RESEARCH AGREEMENT

Not applicable.

### REFERENCE TO AN APPENDIX SUBMITTED ON COMPACT DISC

Not applicable.

### BACKGROUND OF THE INVENTION

1. Field of the Invention

The present invention relates generally to a heat-radiating module, and more particularly to an innovative module which features composite phase-change heat-radiating efficiency.

2. Description of Related Art Including Information Disclosed Under 37 CFR 1.97 and 37 CFR 1.98.

In tune with the high-performance development trend of relevant electronics and computer products, heat-radiating modules are developed to improve heat-radiating efficiency.

Because traditional heat-radiating modules cannot structurally meet the heat-radiating demand of relevant equipment, inventors strive to develop a variety of heat-radiating modules with composite heat-radiating mechanisms, with the purpose of improving the heat-radiating performance. For example, there is a structure combining the cooling pad with a heat pipe (referenced by Taiwanese patent claims in Taiwanese Patent No. 89205047), and there a structure combining the cooling pad with phase-change materials for a brand new processing method (demonstrated by “Heating-Radiating Device” specified in Taiwanese patent claims in Taiwanese Patent No. 93110297 and Taiwanese Patent No. 94128483). This cooling pad is equipped with a chamber to accommodate phase-change materials, which improve the heat-radiating effect to suppress high temperatures through phase transformation (liquid-phase and gas-phase) when reaching a preset temperature.

It is imperative that the heat-radiating modules improve the heat-radiating efficiency. For some products and equipment (e.g. LED) with intermittent operation, it is also urgently required to maintain a certain operating temperature for more smooth startup and operation. In fact, the typical heat-radiating modules are only for improving heat-radiating performance. Therefore, other electronic components are incorporated into the existing products to maintain the operating temperature, leading to higher costs and power consumption.

Thus, to overcome the aforementioned problems of the prior art, it would be an advancement in the art to provide an improved structure that can significantly improve efficacy.

Therefore, the inventor has provided the present invention of practicability after deliberate design and evaluation based on years of experience in the production, development and design of related products.

### BRIEF SUMMARY OF THE INVENTION

Referring to FIG. 2, based on an innovation that the first and second phase-change materials 30, 50 are separately placed into two chambers 20, 40, the phase-change material of higher reaction temperature can assist in heat-absorbing and in preventing overheating. The heat peak is when the cooling pad 10 reaches a preset high-temperature state. When the temperature of the cooling pad 10 declines below the preset temperature, the phase-change material of lower reaction temperature will release the stored latent heat, enabling the cooling pad 10 to maintain its operating temperature and improve the heat-radiating efficiency in response to a variety of equipment.

### BRIEF DESCRIPTION OF THE SEVERAL VIEWS OF THE DRAWINGS

FIG. 1 shows a perspective view of the preferred embodiment of heat-radiating module of the present invention.

FIG. 2 shows a sectional view of the preferred embodiment of heat-radiating module of the present invention.

FIG. 3 shows a graphic illustration of the temperature change curve diagram of the operating state of heat-radiating module of the present invention.

FIG. 4 shows another sectional view of the preferred embodiment of the heat-radiating module of the present invention.

### DETAILED DESCRIPTION OF THE INVENTION

The features and the advantages of the present invention will be more readily understood upon a thoughtful deliberation of the following detailed description of a preferred embodiment of the present invention with reference to the accompanying drawings.

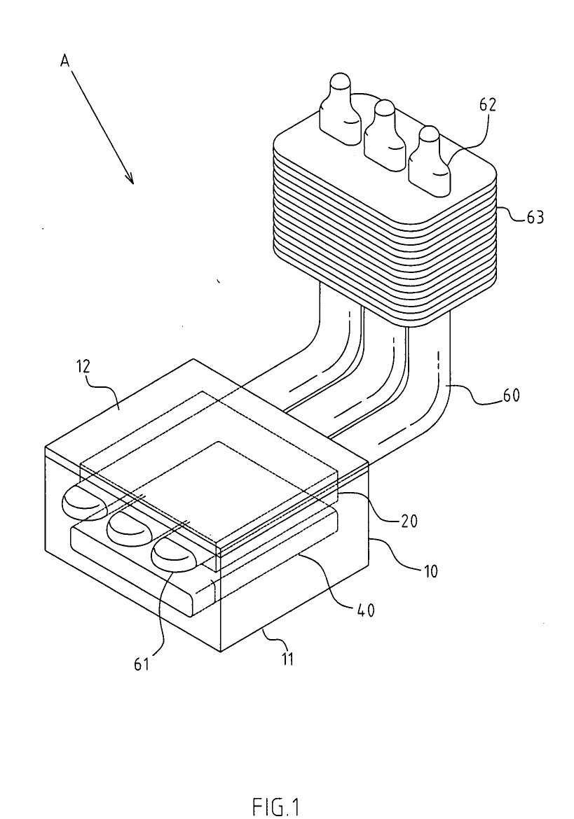

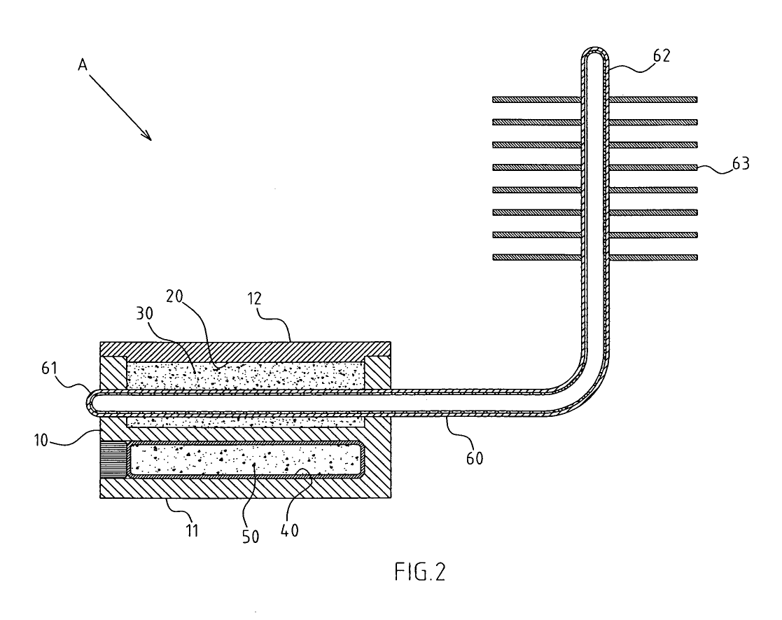

FIGS. 1-2 depict preferred embodiments of a heat-radiating module with composite phase-change heat-radiating efficiency. The embodiments are provided only for explanatory purposes of the patent claims.

The heat-radiating module A comprises a cooling pad 10, which is a predefined three-dimensional structure (e.g. rectangular block), provided with heating portion 11 and radiating portion 12.

A first chamber 20 is assembled at a preset location within the cooling pad 10.

A first phase-change material 30 is placed within the first chamber 20.

A second chamber 40 is assembled into the cooling pad 10 and separated from the first chamber 20.

A second phase-change material 50 is placed within the second chamber 40. The reaction temperature of the second phase-change material 50 and first phase-change material 30 differs from each other.

The radiating portion 12 of the cooling pad 10 is fitted with a heat pipe 60. One end of is a heat-absorbing end 61 penetrating into the first chamber 20 of the cooling pad 10, and the other end is a radiating end 62 protruding from the cooling pad 10. The radiating portion 12 is assembled with a plurality of heat-radiating fins 63.

The phase-change material can generate physical transformation, e.g. transformation between solid and liquid phase. According to physics principles, a melted substance will transform from solid to liquid phase with energy consumption, and the energy will be saved in the form of latent heat as long as the liquid state is maintained. Said latent heat will be released again and transformed from liquid to solid phase, once the liquid substance is solidified. Said phase-change material is made of olefin, inorganic salt, salt hydrate and a mixture, carboxylic acid and sugar alcohol products. In the present invention, the different reaction temperature between the first phase-change material 30 and second phase-change material 50 can be realized through phase-change materials of different properties.

Based upon above-specified structures, the present invention is operated as follows:

Said first and second chambers 20, 40 separately accommodate the first and second phase-change materials 30, 50 of different reaction temperatures. For example, if the reaction temperature of the first phase-change material 30 is set to 40° C. and if the reaction temperature of the second phase-change material 50 is set to 30° C., then the second phase-change material 50 will assist in heat-absorbing and store the latent heat through phase transformation, when the operating temperature of cooling pad 10 exceeds 30° C. Thus, the second phase-change material 50 suppresses and mitigates temperature rise to some extent. Once the heat absorbability of second phase-change material 50 is saturated, the temperature of the cooling pad 10 will rise continuously until reaching 40° C. In such a case, the first phase-change material 30 will generate phase-change and assist in heat-absorbing, making it possible to restrain the temperature of cooling pad 10. Conversely, when the operating temperature of the cooling pad 10 declines below 40° C., the first phase-change material 30 will release the latent heat to slow down the temperature drop until latent heat is fully released. Next, when the operating temperature of the cooling pad 10 declines below 30° C., the first phase-change material 30 will release the latent heat to further slow down the temperature drop. As such, the operating temperature of the cooling pad 10 can be maintained at a preset range (e.g. 30° C. ˜40° C.).

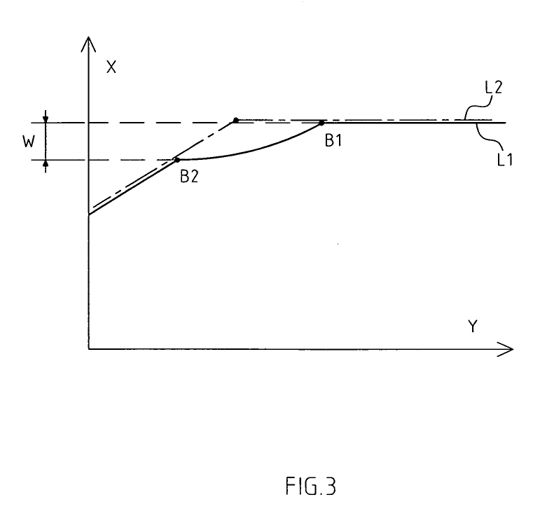

The temperature change is shown in FIG. 3, wherein axis X represents the operating temperature of the cooling pad 10, wherein axis Y represents the operating time of the cooling pad 10, and wherein L1 represents the temperature change curve of the cooling pad. In the curve, point B 1 represents the reaction temperature of the first phase-change material, and point B2 represents the reaction temperature of the second phase-change material. L2 represents the temperature change curve of phase-change materials employed by typical heat-radiating device. It is learnt from the figure that the present invention could prolong considerably the time interval of the preset temperature section (W), so it is particularly suitable for equipment (e.g. LED) that present optimum performance if a basic operating temperature is maintained.

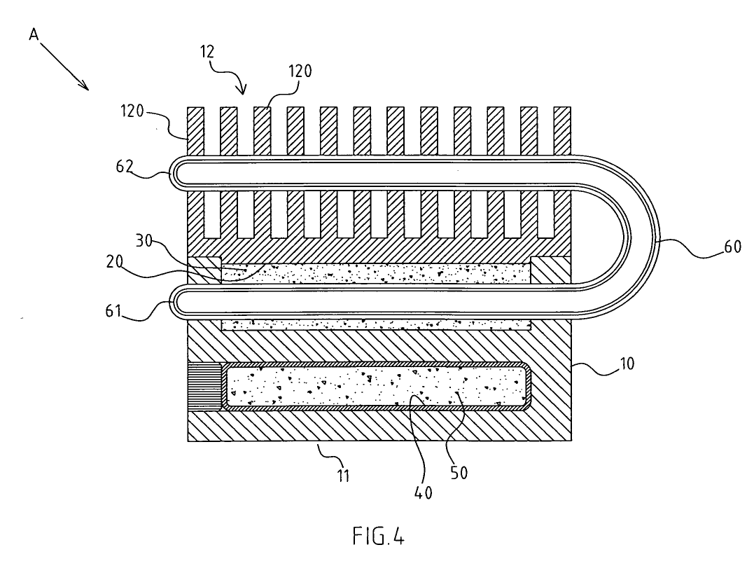

Referring also to FIG. 4, the radiating portion 12 of the cooling pad 10 is also made of a plurality of sheets arranged alternatively on the surface of the cooling pad 10. In this preferred embodiment, the radiating portion 12 of the cooling pad 10 is also equipped with heat pipe 60, and the radiating end 62 of the heat pipe 60 is adapted onto the sheet 120 of the cooling pad 10, thus improving the heat-radiating efficiency.

1. A heat-radiating module with composite phase-change heat-radiating efficiency, said heat-radiating module comprising:
a cooling pad being a predefined three-dimensional structure; and having a heating portion and radiating portion;
a first chamber, being assembled at a preset location within said cooling pad;
first phase-change material, placed within said first chamber;
a second chamber, being assembled into said cooling pad, and separated from said first chamber; and
second phase-change material, placed within the said second chamber, said second phase-change material having a reaction temperature different from a reaction temperature of said first phase-change material.

2. The module defined in claim 1, wherein said radiating portion is fitted with a heat pipe, said heat pipe having heat-absorbing end penetrating into said first chamber of said cooling pad; and a radiating end protruding from said cooling pad, said radiating portion being assembled with a plurality of heat-radiating fins.

3. The module defined in claim 1, wherein said radiating portion is comprised of a plurality of sheets arranged alternatively on a surface of said cooling pad.

4. The module defined in claim 3, wherein said radiating portion is fitted with a heat pipe, said heat pipe having a heat-absorbing end penetrating into said cooling pad, and a radiating end protruding from said cooling pad and coupling with said sheets on said surface.

5. The module defined in claim 1, wherein said phase-change material is selected from a group consisting of: olefin, inorganic salt, salt hydrate, carboxylic acid, sugar alcohol products, and mixtures thereof.
